(19) United States
(12) Patent Application Publication
(10) Pub. No.: US 2007/0281397 A1
(43) Pub. Date: Dec. 6, 2007

(54) Method of forming semiconductor packaged device

(76) Inventor: Wai Yew Lo, Selangor (MY)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/444,448

(22) Filed: May 31, 2006

(51) Int. Cl. H01L 21/00

(52) U.S. Cl. 438/123

(57) ABSTRACT

A method of forming a semiconductor packaged device (10) including die bonding a flip chip die (12) to a first surface (14) of a lead frame (28). A lid (34) is attached to a top surface (36) of the flip chip die (12). A wire bond die (40) is attached to a second surface (22) of the lead frame (28) and electrically connected to the lead frame (28) with wires (44). A mold compound then is formed over the flip chip die (12), the wire bond die (40) and the lead frame (28).

### BACKGROUND OF THE INVENTION

The present invention relates to the packaging of semiconductor devices and more particularly to a method of forming a three-dimensional (3D) semiconductor package.

Three-dimensional semiconductor packages provide a volumetric packaging solution for achieving higher levels of integration, increased performance and greater area efficiency compared to other types of semiconductor packages. Three-dimensional packaging technologies are being developed to overcome performance and real estate limitations encountered with conventional packaging technologies. Accordingly, it would be desirable to have a method of forming a reliable three-dimensional semiconductor package.

### BRIEF DESCRIPTION OF THE DRAWINGS

The following detailed description of a preferred embodiment of the invention will be better understood when read in conjunction with the appended drawings. The present invention is illustrated by way of example and is not limited by the accompanying figures, in which like references indicate similar elements.

FIG. 1 is an enlarged cross-sectional view of a plurality of flip chip dice die bonded to a lead frame panel in accordance with an embodiment of the present invention;

FIG. 2 is an enlarged cross-sectional view of an underfill material disposed between the flip chip dice and the lead frame panel of FIG. 1;

FIG. 3 is an enlarged cross-sectional view of a plurality of lids attached to the respective flip chip dice of FIG. 2;

FIG. 4 is an enlarged cross-sectional view of a tape being removed from a second surface of the lead frame panel of FIG. 3;

FIG. 5 is an enlarged cross-sectional view of a plurality of wire bond dice attached and electrically connected to the lead frame panel of FIG. 4;

FIG. 6 is an enlarged cross-sectional view of the flip chip dice, the lead frame panel and the wire bond dice of FIG. 5 being molded over with a mold compound;

FIG. 7 is an enlarged cross-sectional view of a plurality of semiconductor packaged devices in accordance with an embodiment of the present invention;

FIG. 8 is an enlarged bottom plan view of one of the flip chip dice of FIG. 1;

FIG. 9 is an enlarged top plan view of a lead frame of the lead frame panel of FIG. 1;

FIG. 10 is an enlarged bottom plan view of one of the flip chip dice being die bonded to one of the lead frames of the lead frame panel of FIG. 1; and

FIG. 11 is an enlarged top plan view of one of the wire bond dice attached and electrically connected to one of the lead frames of the lead frame panel of FIG. 5.

### DETAILED DESCRIPTION OF THE PREFERRED EMBODIMENTS

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention. In the drawings, like numerals are used to indicate like elements throughout.

The present invention provides a method of forming a semiconductor packaged device including the step of die bonding a flip chip die to a first surface of a lead frame. A lid is attached to a top surface of the flip chip die. A wire bond die is attached to a second surface of the lead frame and die pads of the wire bond die are electrically connected to respective leads of the lead frame with a plurality of wires. A mold compound is formed over the flip chip die, the wire bond die and the lead frame.

The present invention also provides a method of forming a plurality of semiconductor packaged devices including the step of die bonding a plurality of flip chip dice to a first surface of a lead frame panel. An underfill material is disposed between bottom surfaces of the flip chip dice and the first surface of lead frame panel. A plurality of lids is attached to respective top surfaces of the flip chip dice. A plurality of wire bond dice is attached to a second surface of the lead frame panel and die pads thereof are electrically connected to respective leads of the lead frame panel with a plurality of wires. A mold compound then is formed over the flip chip dice, the wire bond dice and the lead frame panel.

The present invention further provides a method of forming a semiconductor packaged device including the step of die bonding a flip chip die to a first side of a lead frame, the lead frame having a tape attached to a second side thereof. The tape is removed from the second side of the lead frame. A wire bond die is attached to a second side of the lead frame and electrically connected to respective leads of the lead frame with a plurality of wires. A mold compound then is formed over the flip chip die, the wire bond die and the lead frame.

FIGS. 1 through 7 illustrate a method of forming a plurality of semiconductor packaged devices 10 in accordance with an embodiment of the present invention.

Referring now to FIG. 1, a plurality of flip chip dice 12 is die bonded to a first surface or side 14 of a lead frame panel 16 as shown. The lead frame panel 16 comprises a plurality of lead frames, each lead frame defining a die bonding site to which respective ones of the flip chip dice 12 are bonded. Solder balls, such as controlled collapse chip connection (C4) type interconnections 18, are formed between the flip chip dice 12 and the lead frame panel 16. In the embodiment shown, a tape 20 is attached to a second surface or side 22 of the lead frame panel 16.

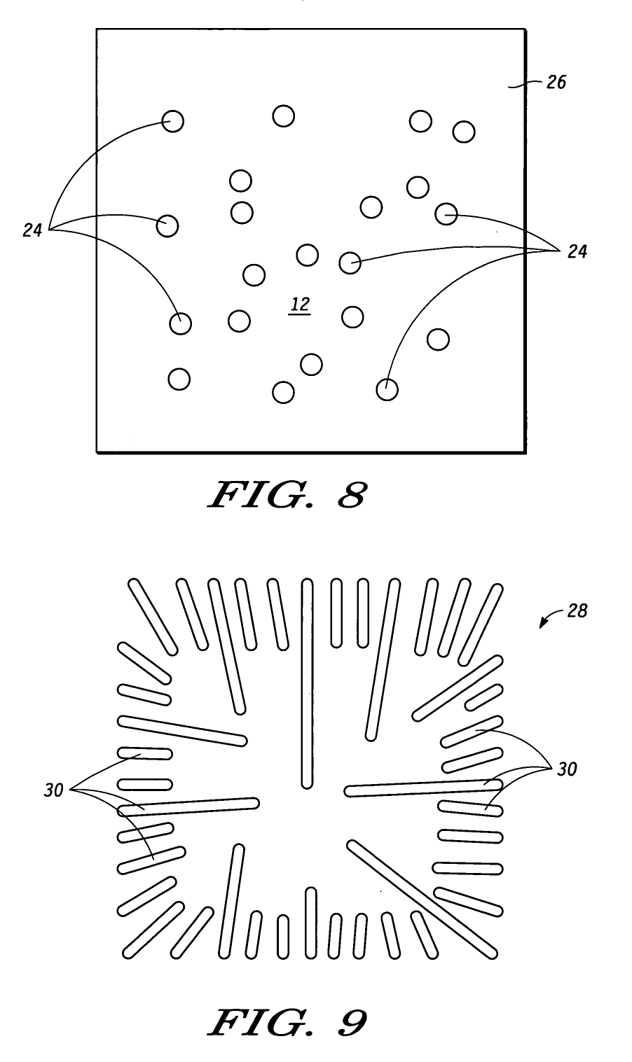

The flip chip dice 12 may be any type of circuit such as, for example, a digital signal processor (DSP) or a special function circuit. The flip chip dice 12 are not limited to a particular technology such as CMOS, or derived from any particular wafer technology. Further, the present invention can accommodate flip chip dice 12 of various sizes; for example, the flip chip dice 12 may be about 15 millimetres (mm) by about 15 mm in size. An enlarged bottom plan view of one of the flip chip dice 12 is shown in FIG. 8. As shown in FIG. 8, the flip chip die 12 includes a plurality of bumps 24 on a bottom surface 26 thereof. The bumps 24 are distributed across the bottom surface 26 of the flip chip die 12 in a predetermined pattern, such as an area array configuration. However, it should be understood that the present invention is not limited by the arrangement of the bumps 24 on the bottom surface 26 of the flip chip die 12. The present invention may, for example, accommodate flip chip dice 12 with peripheral array bumps 24 in alternative embodiments. The bumps 24 are made of a conductive metal such as gold, copper, or a metal alloy and are formed on the flip chip die 12 using a known wafer bumping process. Such flip-chip bumped dice 12 are known by those of skill in the art and therefore, further explanation is not necessary for a complete understanding of the invention.

Referring again to FIG. 1, the lead frame panel 16 may be formed from a copper or metal alloy sheet or strip via etching or stamping, as is known in the art. The lead frame panel 16 also may be plated. In the embodiment shown, the lead frame panel 16 comprises a strip of three (3) lead frames. Nonetheless, those of skill in the art will understand that the present invention is not limited by the arrangement of the lead frames or the number of lead frames in the lead frame panel 16. For example, the lead frame panel 16 may comprise an array of nine (9) lead frames arranged in a 3×3 matrix. In one embodiment, the lead frame panel 16 comprises a plurality of Quad Flat Pack (QFP) type lead frames. An enlarged top plan view showing leads 30 of one of the lead frames 28 of the lead frame panel 16 is shown in FIG. 9. As shown in FIG. 9, the leads 30 need not be of uniform length. That is, some of the leads may extend into an inner region of the lead frame 28.

Referring again to FIG. 1, the tape 20 provides support to the leads 30 of the lead frames 28 and thus facilitates die bonding of flip chip dice 12 having area array bumps 24 to the lead frames 28 of the lead frame panel 16. The tape 20 may be an adhesive film made of polymeric material. In one embodiment, the tape 20 has a thickness of about 0.1 mm.

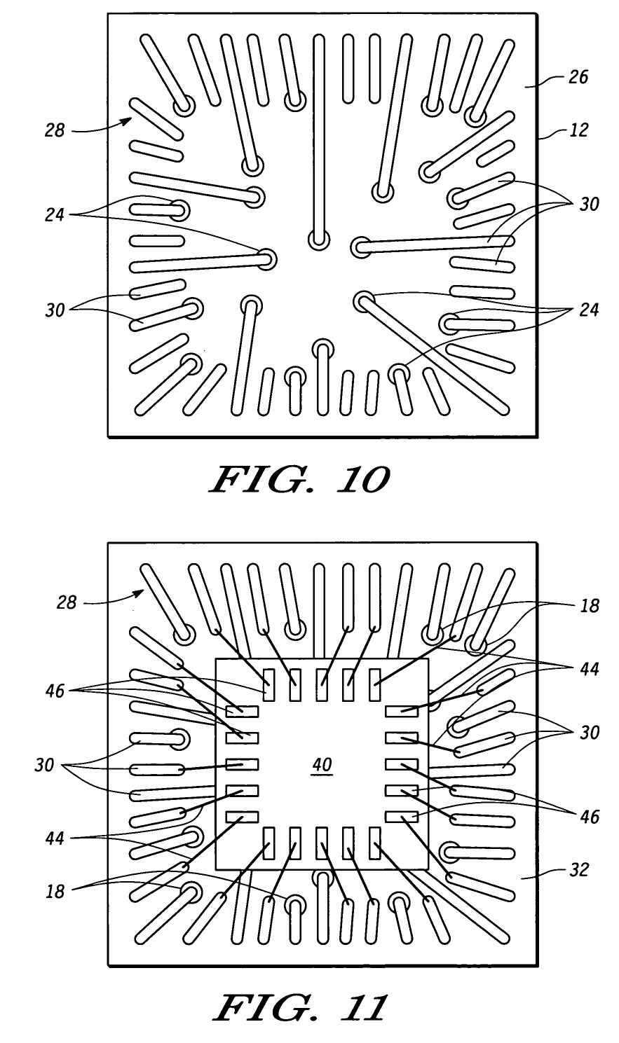

The process of die bonding the flip chip dice 12 to respective ones of the lead frames 28 of the lead frame panel 16 will now be described with reference to FIGS. 1 and 10. FIG. 10 shows an enlarged bottom plan view of one of the flip chip dice 12 being die bonded to one of the lead frames 28 of the lead frame panel 16. As shown in FIG. 4, the bumps 24 on the bottom surface 26 of the flip chip die 12 are placed against corresponding ones of the leads 30 of the lead frame 28. A reflow process is performed on the bumps 24 to form C4 type interconnections between the flip chip dice 12 and the lead frame panel 16. The reflow process is performed on the bumps 24 by passing the flip chip dice 12 and the lead frame panel 16 through a reflow oven. For example, the lead frame panel 16 may be placed on a conveyor belt that passes through a reflow oven. The reflow process may be performed using known methods of reflow attachment such as, for example, Infrared Radiation (IR) Reflow, Vapour Phase Reflow and Hot Air Convection Reflow. The heat in the reflow oven melts the bumps 24. The melted bumps 24 wet the leads 30 of the lead frames 28 and form C4 type interconnections between the flip chip dice 12 and the lead frames 28 on cooling.

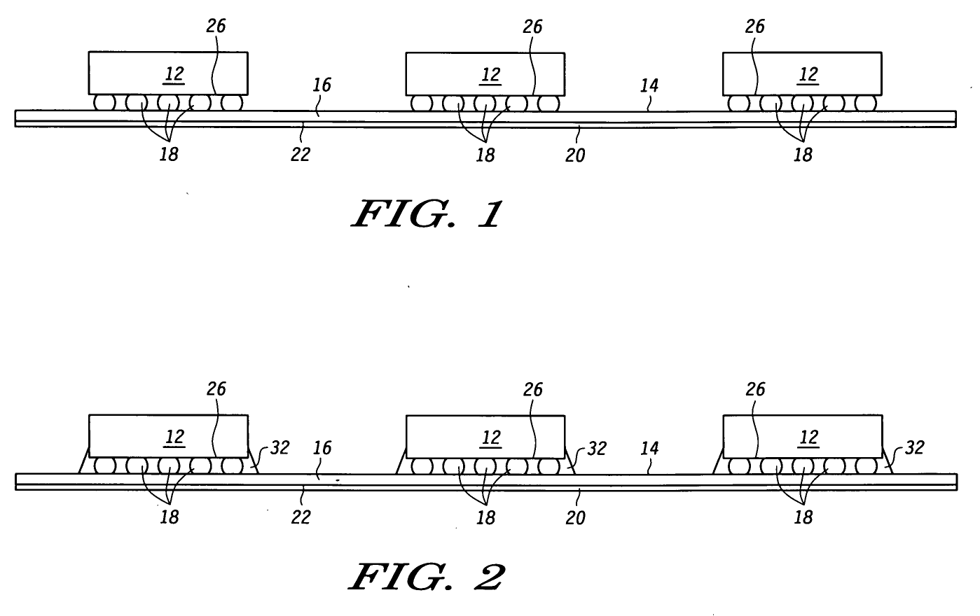

Referring now to FIG. 2, an underfill material 32 is disposed between the bottom surfaces 26 of the flip chip dice 12 and the first surface 14 of lead frame panel 16 as shown. More particularly, the underfill material 32 is disposed beneath the flip chip dice 12 and around the C4 type interconnections 18 such that the underfill material 32 encapsulates the C4 type interconnections 18. The tape 20 attached to the second surface 22 of the lead frame panel 16 prevents flow of the underfill material 22 to the second surface 22 of the lead frame panel 16, thereby preventing contamination of the second surface 22 of the lead frame panel 16 by the underfill material 32.

The underfill material 32 aids in securing the flip chip dice 12 and the C4 type interconnections 18 to the lead frames 28 of the lead frame panel 16, and protects the flip chip dice 12 and the C4 type interconnections 18 from mechanical stresses during subsequent processing steps. The underfill material 32 preferably is disposed between the flip chip dice 12 and the lead frames 28 of the lead frame panel 16 via a capillary flow underfill process. The underfill material 32 is subsequently cured. Because the capillary flow underfill process relies on capillary action to fill the space between the flip chip dice 12 and the lead frames 28, minimal forces are exerted on the C4 type interconnections 18 during the capillary flow underfill process. Accordingly, good package reliability is achieved by encapsulating the C4 type interconnections 18 via the capillary flow underfill process. The underfill material 32 preferably is a low modulus underfill such as, Loctite low modulus underfill material. The use of a low modulus underfill in the capillary flow underfill process reduces stresses on the flip chip dice 12 during the underfill process. Accordingly, such an embodiment of the present invention may be used to package flip chip dice 12 with low dielectric constants (i.e., low K dice) and flip chip dice 12 that are prone to interlayer dielectric (ILD) cracking. Nevertheless, it should be understood that the present invention is not limited by the underfill process employed or the composition of the underfill material 32. For example, the underfill material 32 may be pre-applied in alternative embodiments.

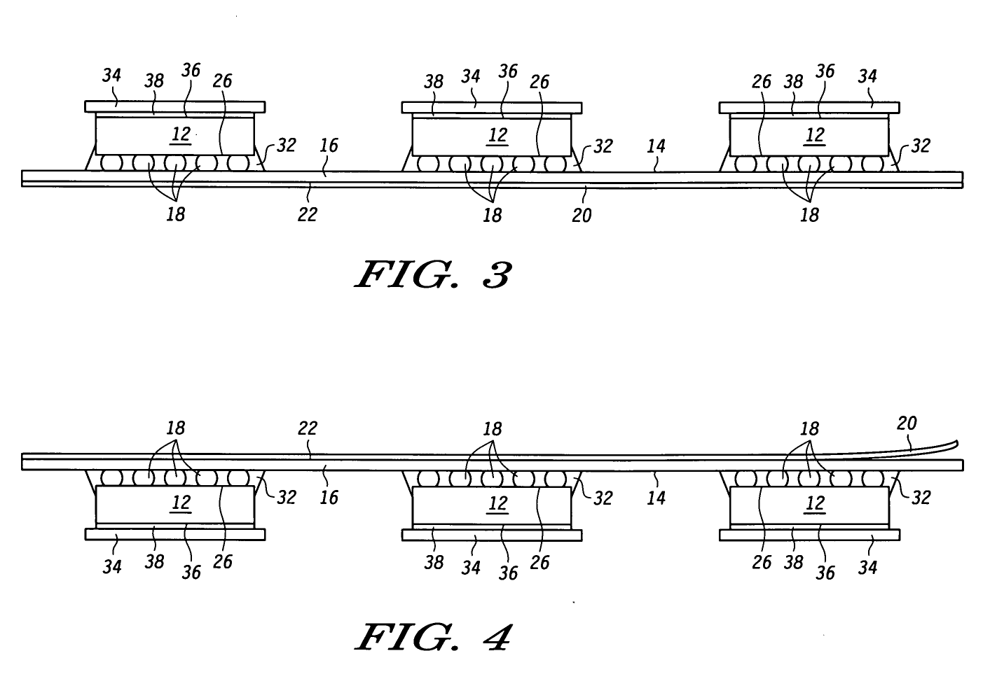

Referring now to FIG. 3, a plurality of lids or heat spreaders 34 is attached to respective top surfaces 36 of the flip chip dice 12 with an adhesive 38 as shown. The lids 34 are made of a thermally conductive material such as copper, aluminium or nickel, and have a thickness of about 0.5 mm. In one embodiment, the lids 34 are attached to the flip chip dice 12 by dispensing the adhesive 38 onto the respective top surfaces 36 of the flip chip dice 12, placing the lids 34 over the respective flip chip dice 12 and curing the adhesive 38. The adhesive 38 may be an epoxy, metal filled epoxy or silicon material. Such adhesives 38 are known in the art and commercially available. Of course, for parts that do not generate a lot of heat, lids may not be necessary.

Referring now to FIG. 4, the tape 20 is removed from the second surface 22 of the lead frame panel 16. As shown in FIG. 4, the flip chip dice 12 and the lead frame panel 16 are flipped or turned over for the removal of the tape 20 from the second surface 22 of the lead frame panel 16.

Referring now to FIG. 5, a plurality of wire bond dice 40 is attached and electrically connected to the second surface 22 of the lead frame panel 16 as shown. The wire bond dice 40 are attached to the respective lead frames 28 of the lead frame panel 16 with a die attach adhesive 42 and die pads of the dice 40 are electrically connected to the respective leads of the lead frames 28 with a plurality of wires 44. The underfill material 32 disposed between the flip chip dice 12 and the first surface 14 of the lead frame panel 16 and around the C4 type interconnections 18 protects the flip chip dice 12 and the C4 type interconnections from damage during the die attach and wire bonding of the wire bond dice 40 to the second surface 22 of the lead frame panel 16.

The wire bond dice 40 may be any type of circuit such as, for example, a digital signal processor (DSP) or a special function circuit. The wire bond dice 40 are not limited to a particular technology such as CMOS, or derived from any particular wafer technology. Further, the present invention can accommodate wire bond dice 40 of various sizes; for example, the wire bond dice 40 may be about 15 mm by about 15 mm in size.

In one embodiment, the wire bond dice 40 are attached to the respective lead frames 28 of the lead frame panel 16 by dispensing the die attach adhesive 42 onto respective bonding sites on the second surface 22 of the lead frame panel 16, placing the wire bond dice 40 on the respective bonding sites on the lead frame panel 16, and curing the die attach adhesive 42. The die attach adhesive 42 may be a non-conductive liquid epoxy or a tape epoxy. Such epoxies are known in the art and commercially available. Tape epoxies are preferred in embodiments where the ends of the leads 30 of the lead frames 28 extending inwards towards the respective bonding sites are in close proximity to respective edges of the wire bond dice 40.

The wires 44 may be made of gold (Au), copper (Cu), aluminium (Al) or other electrically conductive materials as are known in the art and commercially available. A known wire bonding process is used to form the electrical connections. Referring now to FIG. 11, an enlarged top plan view of one of the wire bond dice 40 attached and electrically connected to one of the bonding sites on the second surface 22 of the lead frame panel 16 is shown. The wires 44 electrically connect bond pads 46 on the wire bond die 40 to respective ones of the leads 30 of one of the lead frames 28 of the lead frame panel 16. In the embodiment shown, the wires 44 electrically connect the bond pads 46 on the wire bond die 40 to the leads 30 of the lead frame 28 that are not already connected to one of the flip chip dice 12 via the C4 type interconnections 18. The leads 30 of the lead frame 28 may be plated with a conductive metal such as, for example, tin or gold, or a conductive alloy.

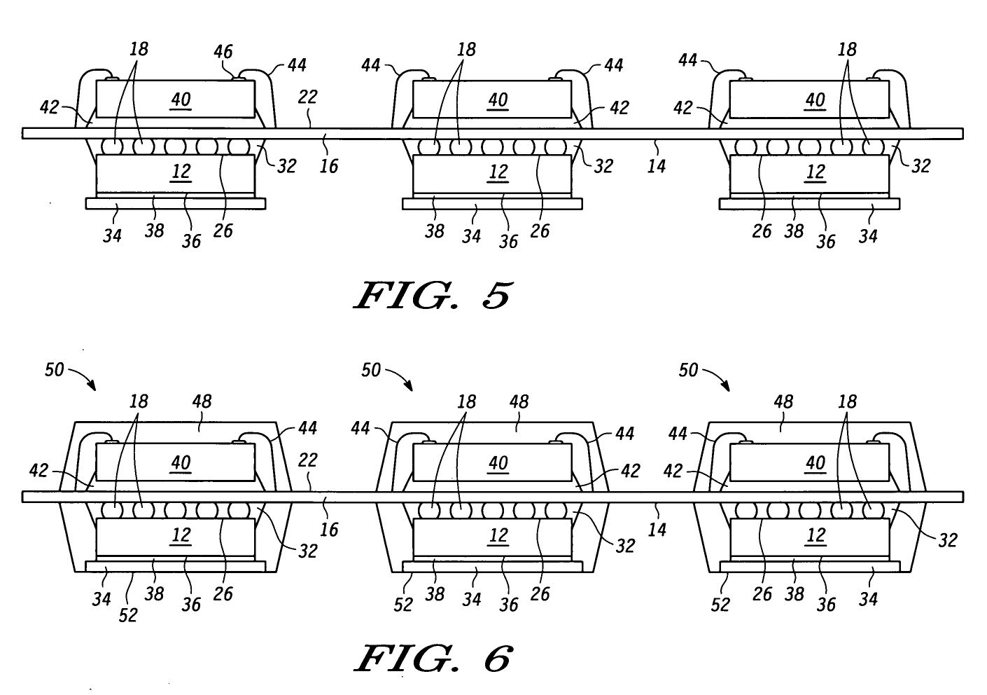

Referring now to FIG. 6, a mold compound 48 is formed over the flip chip dice 12, the lead frame panel 16 and the wire bond dice 40 to form a plurality of flip chip and wire bond die assemblies 50. The mold compound 48 encapsulates a portion of the lids 34, leaving a surface 52 of the lids 34 exposed. A well known molding process such as, for example, injection molding may be performed to encapsulate the flip chip dice 12, the lead frame panel 16 and the wire bond dice 40. The mold compound 48 may comprise well known commercially available molding materials such as plastic or epoxy.

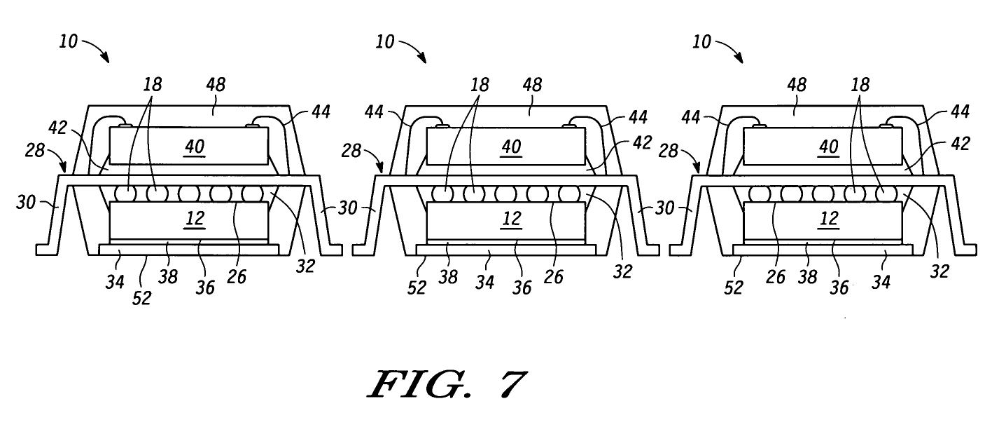

Referring now to FIG. 7, a trim and form operation is performed on the lead frame panel 16 to separate adjacent ones of the flip chip and wire bond die assemblies 50 into individual semiconductor packaged devices 10. The leads 30 of the semiconductor packaged devices 10 are subsequently cleaned and plated with a metal such as, for example, tin (Sn) or solder to protect the leads 30 against abrasion and corrosion, and to improve the solderability and appearance of the leads 30. In the embodiment shown, the leads 30 are formed into gull wing (GW) leads. Nonetheless, those of skill in the art will understand that the semiconductor packaged devices 10 of the present invention are not limited to having GW leads. For example, the leads 30 may be J-shaped in alternative embodiments. The exposed surfaces 52 of the lids 34 provide an avenue for dissipating the heat generated within the semiconductor packaged devices 10. This enhances the thermal performance of the semiconductor packaged devices 10.

Although the semiconductor packaged devices 10 of the present embodiment include only one (1) wire bond die 40, it should be understood that the present invention is not limited by the number of wire bond dice 40 attached and electrically connected to each bonding site on the second surface 22 of the lead frame panel 16. In alternative embodiments, stacks of two (2) or more wire bond dice 40 may be attached and electrically connected to the second surfaces 22 of each of the lead frames 28 of the lead frame panel 16. Additionally, although FIGS. 1 to 7 show the formation of only three (3) semiconductor packaged devices 10, it will be understood that fewer or more semiconductor packaged devices 10 may be formed simultaneously with the present invention.

As is evident from the foregoing discussion, the present invention provides a method of forming a reliable three-dimensional semiconductor package having both a flip chip die and a wire bond die encapsulated therein. Underfill material disposed between the flip chip die and a first side of the lead frame protects the flip chip die and the C4 type interconnections formed between the flip chip die and the lead frame from damage during the subsequent attachment and electrical connection of the wire bond die to a second surface of the lead frame. A tape attached to the second side of the lead frame prevents contamination of the second side of the lead frame by the underfill material during the underfill process. Additionally, the tape provides support to the lead frame during the flip chip die bonding process. This enables die bonding of a flip chip die with area array bumps to the lead frame. Further, the provision of a lid with an exposed surface enhances the thermal performance of the semiconductor packaged device formed with the present invention. Advantageously, the present invention is manufacturable, as it can be implemented with existing equipment and processes. Furthermore, by bonding the flip chip die and the wire bond die on opposite sides of the lead frame, a semiconductor packaged device with a relatively thin profile is formed.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiments disclosed, but covers modifications within the spirit and scope of the present invention as defined by the appended claims.

1. A method of forming a semiconductor packaged device, comprising:
attaching a flip chip die to a first surface of a lead frame;
attaching a lid to a top surface of the flip chip die;
attaching a wire bond die to a second surface of the lead frame;
electrically connecting die pads of the wire bond die to respective leads of the lead frame with a plurality of wires; and
molding over the flip chip die, the wire bond die and the lead frame.

2. The method of forming a semiconductor packaged device according to claim 1, further comprising disposing an underfill material between a bottom surface of the flip chip die and the first surface of lead frame.

3. The method of forming a semiconductor packaged device according to claim 2, wherein the underfill material is disposed between the flip chip die and the lead frame via a capillary flow underfill process.

4. The method of forming a semiconductor packaged device according to claim 2, further comprising curing the underfill material.

5. The method of forming a semiconductor packaged device according to claim 1, further comprising attaching a tape to the second surface of the lead frame prior to attaching the flip chip die to the first surface of the lead frame.

6. The method of forming a semiconductor packaged device according to claim 5, further comprising removing the tape from the second surface of the lead frame prior to attaching the wire bond due to the second surface of the lead frame.

7. The method of forming a semiconductor packaged device according to claim 1, wherein the step of attaching the flip chip die comprises performing a reflow process on a plurality of bumps on a bottom surface of the flip chip die to form C4 type interconnections between the flip chip die and the lead frame.

8. The method of forming a semiconductor packaged device according to claim 7, wherein the C4 type interconnections formed between the flip chip die and the lead frame are distributed in an area array configuration.

9. The method of forming a semiconductor packaged device according to claim 1, wherein the lid attachment step further comprises dispensing an adhesive onto the top surface of the flip chip die, placing the lid over the flip chip die, and curing the adhesive.

10. The method of forming a semiconductor packaged device according to claim 1, wherein the wire bond die attachment step further comprises dispensing a die attach adhesive onto the second surface of the lead frame, placing the wire bond die over the second surface of the lead frame, and curing the die attach adhesive.

11. The method of forming a semiconductor packaged device according to claim 1, wherein the molding step comprises molding over a portion of the lid, wherein a surface of the lid is exposed.

12. The method of forming a semiconductor packaged device according to claim 1, further comprising performing a trim and form operation on the lead frame.

13. A method of forming a plurality of semiconductor packaged devices, comprising:
attaching a plurality of flip chip dice to a first surface of a lead frame panel;
disposing an underfill material between bottom surfaces of the flip chip dice and the first surface of lead frame panel;
attaching a plurality of lids to respective top surfaces of the flip chip dice;
attaching a plurality of wire bond dice to a second surface of the lead frame panel;
electrically connecting die pads of the wire bond dice to respective leads of the lead frame panel with a plurality of wires; and
molding over the flip chip dice, the wire bond dice and the lead frame panel, thereby forming a plurality of flip chip and wire bond die assembles.

14. A method of forming a plurality of semiconductor packaged devices according to claim 13, further comprising performing a trim and form operation on the lead frame panel to separate adjacent ones of respective flip chip and wire bond die assemblies into individual semiconductor packaged devices.

15. A method of forming a plurality of semiconductor packaged devices according to claim 13, further comprising:
attaching a tape to the second surface of the lead frame panel prior to attaching the flip chip dice to the first surface of the lead frame panel; and
removing the tape from the second surface of the lead frame panel prior to attaching the wire bond dice to the second surface of the lead frame panel.

16. A method of forming a semiconductor packaged device, comprising:
attaching a tape to a second side of a lead frame;
die bonding a flip chip die to a first side of the lead frame;
removing the tape from the second side of the lead frame;
attaching a wire bond die to the second side of the lead frame;
electrically connecting die pads on the wire bond die to respective leads of the lead frame with a plurality of wires; and
forming a mold compound over the flip chip die, the wire bond die and the lead frame.

17. The method of forming a semiconductor packaged device according to claim 16, further comprising attaching a lid to a top surface of the flip chip die.

18. The method of forming a semiconductor packaged device according to claim 16, wherein the die bonding step further comprises performing a reflow process on a plurality of bumps on a bottom surface of the flip chip die to form C4 type interconnections between the flip chip die and the lead frame.

19. The method of forming a semiconductor packaged device according to claim 18, further comprising disposing an underfill material beneath the flip chip die and around the C4 type interconnections.

20. The method of forming a semiconductor packaged device according to claim 16, further comprising performing a trim and form operation on the lead frame.
